(19) United States
(12) Patent Application Publication
(10) Pub. No.: US 2013/0045595 A1
(43) Pub. Date: Feb. 21, 2013

(54) METHOD FOR PROCESSING METAL LAYER

(71) Applicants: Tsun-Min Cheng, Changhua County (TW); Chien-Chao Huang, Hsinchu City (TW); Chin-Fu Lin, Tainan City (TW); Chi-Mao Hsu, Tainan City (TW); Yen-Liang Lu, Kaohsiung City (TW); Chun-Ling Lin, Tainan City (TW)

(72) Inventors: Tsun-Min Cheng, Changhua County (TW); Chien-Chao Huang, Hsinchu City (TW); Chin-Fu Lin, Tainan City (TW); Chi-Mao Hsu, Tainan City (TW); Yen-Liang Lu, Kaohsiung City (TW); Chun-Ling Lin, Tainan City (TW)

(21) Appl. No.: 13/210,380

(22) Filed: Aug. 16, 2011

(51) Int. Cl. H01L 21/283

(52) U.S. Cl. 438/661; 257/E21.159

(57) ABSTRACT

The method for processing a metal layer including the following steps is illustrated. First, a semiconductor substrate is provided. Then, a metal layer is formed over the semiconductor substrate. Furthermore, a microwave energy is used to selectively heat the metal layer without affecting the underlying semiconductor substrate and other formed structures, in which the microwave energy has a predetermined frequency in accordance with a material of the metal layer, and the predetermined frequency ranges between 1 KHz to 1 MHz.

### BACKGROUND OF THE INVENTION

1. Field of the Invention

The present invention relates to a method for processing a metal layer, and more particularly, to a method for selectively heating the metal layer without affecting the underlying substrate or the formed structures.

2. Description of the Prior Art

With the increasing packing density of the semiconductor devices, the pitches of the critical dimension elements such as the metal interconnect structures decrease as well. Furthermore, for manufacturing the metal interconnect structures, the metal layer is commonly deposited on the patterned dielectric layer which covers the underlying formed structures. The demand for the smaller pitch and the stepped topography adversely affect the formation of the metal layer, accordingly, the structural defects such as voids are found within the metal interconnect structure. These defects may cause a reduction of production yield due to shorts between the adjacent interconnect lines and the inferior performance of the semiconductor devices.

Accordingly, how to establish a method for processing the metal layer to improve the integrity of the metal interconnect structure and the reliability of semiconductor device performance is still an important issue in the field.

### SUMMARY OF THE INVENTION

An objective of the present invention is to provide a method for processing a metal layer to improve the integrity of the metal interconnect structure and the reliability of semiconductor device performance.

According to one exemplary embodiment of the present invention, the method for processing a metal layer includes the following steps. First, a semiconductor substrate is provided. Then, a metal layer is formed over the semiconductor substrate. Furthermore, a microwave energy is used to selectively heat the metal layer, in which the microwave energy has a predetermined frequency in accordance with a material of the metal layer, and the predetermined frequency ranges between 1 KHz to 1 MHz.

The present invention utilizes microwave energy for processing the metal layer on the semiconductor substrate, the microwave energy has a predetermined frequency depending on a material of the metal layer, and the predetermined frequency ranges between 1 KHz to 1 MHz. Because the induced current provided by the microwave energy is centered on the surface of the metal layer as a heating source, the microwave energy may selectively heat the metal layer without affecting the underlying semiconductor substrate and other formed structures. This method may also be integrated into the metal interconnect process of small dimensional structures of 20 nm and beyond to overcome the constraint of the metal layer formation process such as CVD process or PVD process, consequently, the void free metal interconnect structure could be obtained for facilitating the reliability of semiconductor device performance.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 through FIG. 6 illustrate a method for processing a metal layer according to the first exemplary embodiment of the present invention.

FIG. 7 through FIG. 9 illustrate a method for processing a metal layer according to the second exemplary embodiment of the present invention.

FIG. 10 is a flow chart illustrating a method for processing a metal layer according to an exemplary embodiment of the present invention.

### DETAILED DESCRIPTION

To provide a better understanding of the present invention, preferred embodiments will be made in detail. The preferred embodiments of the present invention are illustrated in the accompanying drawings with numbered elements.

The present invention may be applied in various semiconductor processes such as the metal interconnect process and the metal gate process etc. Process for manufacturing a single damascene process and process for selectively heating a metal layer are combined and taken as the first exemplary embodiment. Please refer to FIG. 1 through FIG. 6. FIG. 1 through FIG. 6 illustrate a method for processing a metal layer according to the first exemplary embodiment of the present invention. As shown in FIG. 1, a semiconductor substrate 10, such as a silicon substrate or a silicon-on-insulator (SOI) substrate, is provided. The semiconductor substrate 10 may include at least a conductive region 12 formed by the previous integrated circuit manufacturing process. The conductive region 12 may include the source/drain region, the gate of metal-oxide-semiconductor (MOS) device, or metal conductive layer such as metal conducting lines, but not limited thereto. A first layer 14 is formed on the semiconductor substrate 10 through chemical vapor deposition (CVD) process. The first layer 14 could be an insulating layer, and a material of the first layer 14 may include low-k (low dielectric constant) material, for example, a silicon oxide based material. The first layer 14 may be an inter-metal dielectric (IMD) layer herein, but not limited thereto, in other exemplary embodiment, the first layer 14 could be an inter-level dielectric (ILD) layer as well.

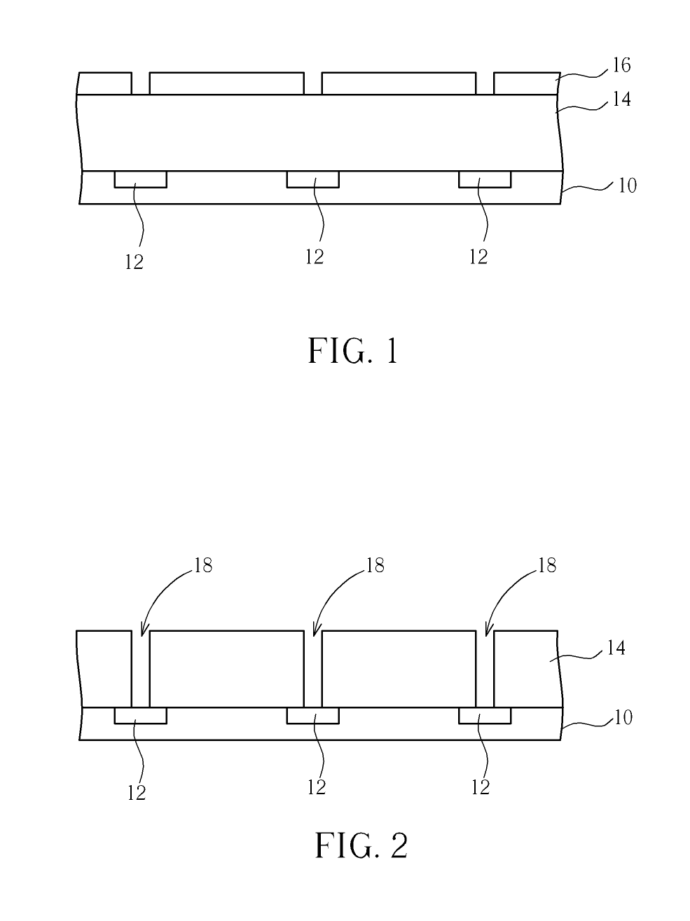

Furthermore, a patterned photoresist layer 16 is formed on the first layer 14, and a pattern transfer is conducted by using the patterned photoresist layer 16 as a mask through single or multiple etching processes to remove a portion of the first layer 14. As shown in FIG. 2, after stripping the patterned photoresist layer 16, the first layer 14 having a stepped surface is formed on the semiconductor substrate 10. The stepped surface of the first layer 14 includes a plurality of openings 18 which may expose the conductive regions 12 of the semiconductor substrate 10. As the first layer 14 is an IMD layer, the opening 18 may be a via hole, a trench or a plug hole herein, but not limited thereto. In other exemplary embodiment, as the first layer 14 is an ILD layer, the opening 18 could be a contact hole, a trench or a plug hole.

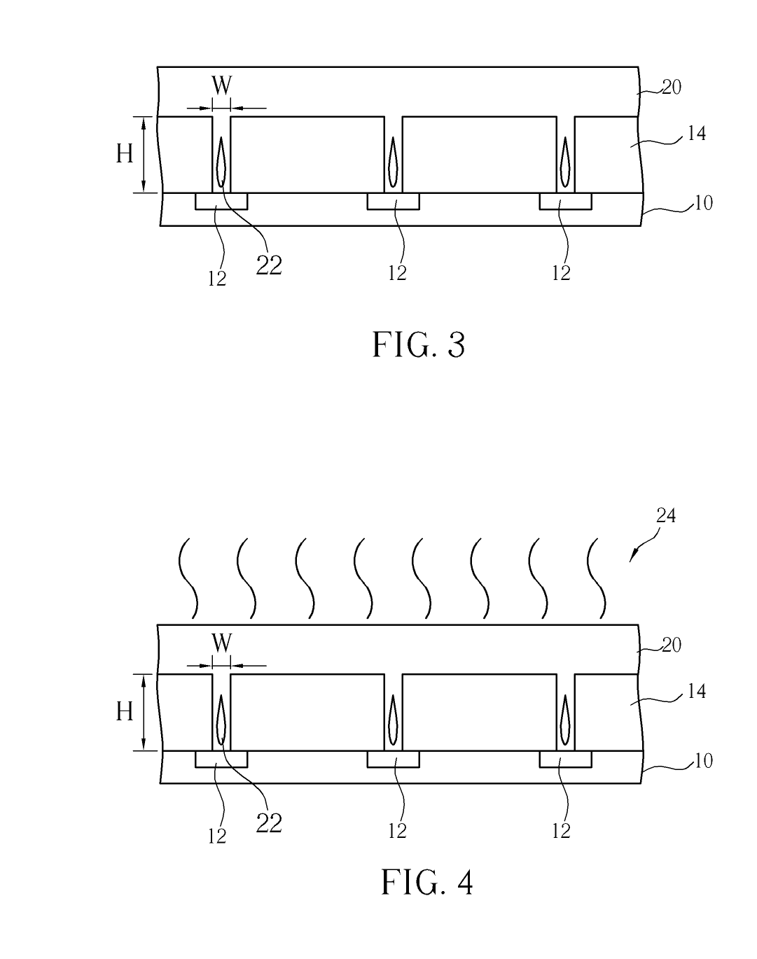

Next, as shown in FIG. 3, through CVD process, physical vapor deposition (PVD) process or electro-chemical plating (ECP) process, a metal layer 20 is formed over the semiconductor substrate 10, cover the first layer 14 and fill the openings 18. A material of the metal layer 20 may include aluminum (Al), tungsten (W) or copper (Cu), but not limited thereto. Additionally, in order to enhance the adhesion between the metal layer 20 and the semiconductor substrate 10, a barrier layer or a seed layer made of titanium (Ti), titanium nitride (TiN), tantalum (Ta), tantalum nitride (TaN) could be selectively formed between the metal layer 20 and the semiconductor substrate 10. With a trend towards scaling down the critical dimension elements, the smaller pitches such as 20 nm and beyond may elevate the aspect ratio of the opening 18. Accordingly, the metal layer 20 formed through the combination of the deposition process such as CVD process or PVD process and the photolithography process could not overall contact the first layer 14, i.e. it is difficult to fill up the openings 18 well with the metal layer 20. In other words, as the opening 18 has a ratio of a height H of the opening 18 to a width W of the opening 18 substantially greater than 4, i.e. H/W>4, some structural defects such as void structures 22 may be formed in the opening 18 between the metal layer 20 and the semiconductor substrate 10.

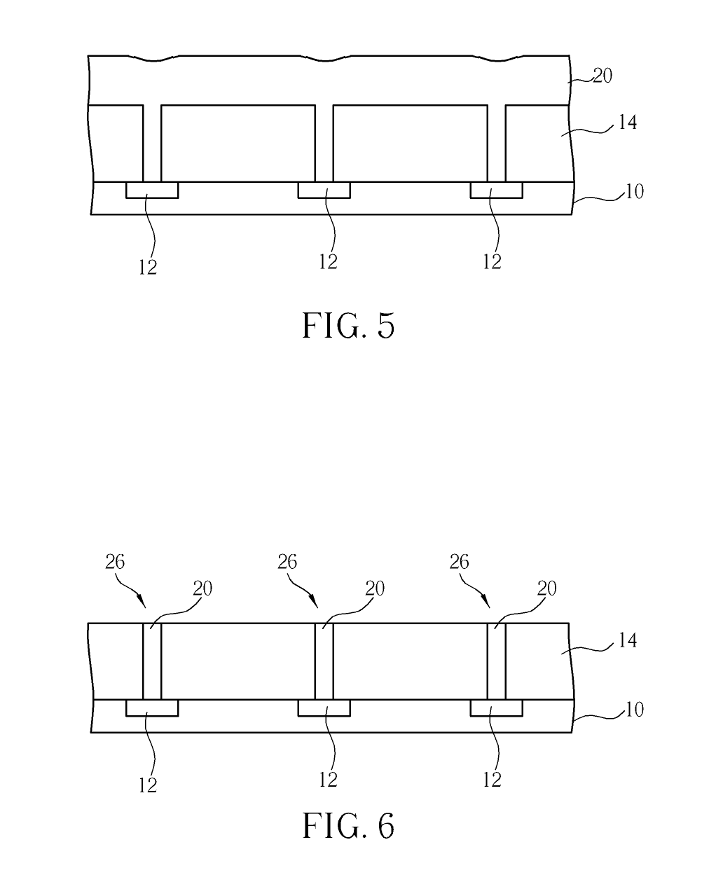

For compensating the phenomenon, as shown in FIG. 4, a microwave energy 24 is used to selectively heat the metal layer 20. The utilization of the microwave energy 24 makes a temperature of the metal layer 20 increase, consequently, as shown in FIG. 5, the metal layer 20 may reflow to fill up the void structures 22 by the thermal treatment of the selective heating. The induced current provided by the microwave energy 24 is centered on the surface of the metal layer 20 as a heating source of the selective heating. Thus, the structural defects are reduced without redundant heat affecting the underlying semiconductor substrate 10 and other formed structures such as the conductive regions 12 or the salicide layer (not shown) further disposed on the conductive region 12 for lowering the resistance between the later formed metal interconnect structure and the conductive regions 12. It is appreciated that, the conventional thermal treatment employing the furnace to entirely heat the semiconductor substrate 10, so that the performance of the overall formed structures may be influenced by the raised temperature. Accordingly, the present invention provides the microwave energy 24 having a predetermined frequency in accordance with a material of the metal layer 20 to selectively heat the metal layer 20 and the predetermined frequency ranges between 1 KHz to 1 MHz. That is, the material of the metal layer 20 determines the value of the predetermined frequency within the feasible range. For example, as the metal layer 20 is made of aluminum (Al), the preferred operating condition of the microwave energy 24 may include an operating frequency as 600 KHz and an operating period as 60 seconds. Furthermore, the operation could be performed under vacuum or 1 atmosphere (atm) in inert gas, and the operating temperature is preferably below 400 degrees centigrade (C).

Afterward, as shown in FIG. 6, a planarization process such as a chemical mechanical polish (CMP) process is performed to remove the excess portion of the metal layer 20 above the first layer 14 to complete the formation of the metal interconnect structure 26 as a single damascene structure. With the implementation of the microwave energy 24, the void free metal interconnect structure 26 is obtained.

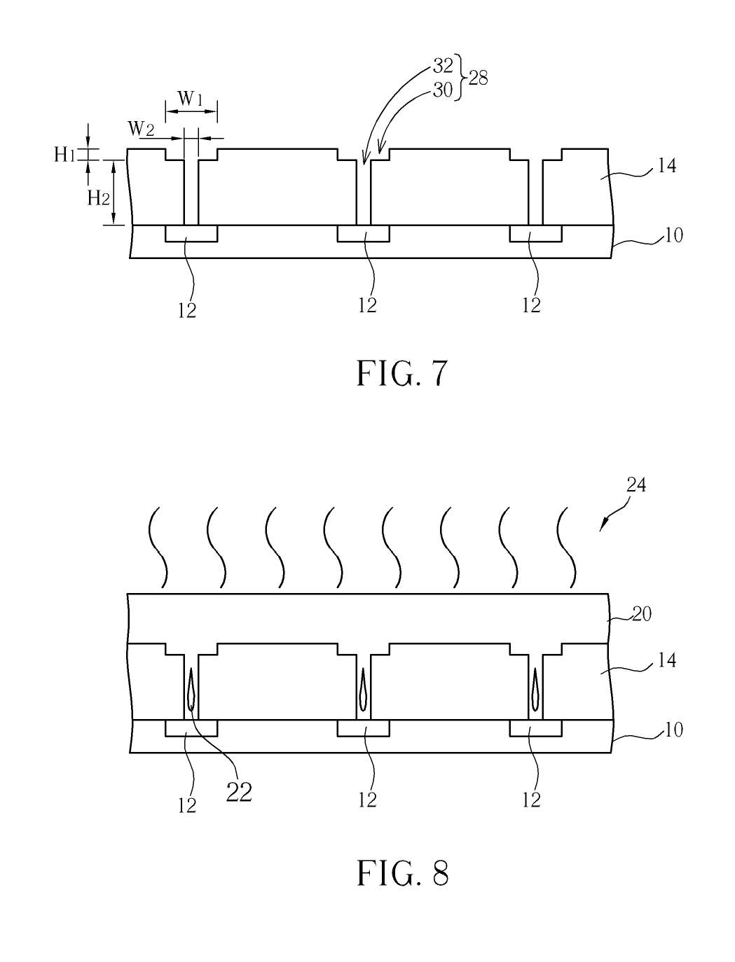

The method for processing a metal layer of the present invention is not limited to the previous illustrated exemplary embodiment. The combination of the dual damascene manufacturing process and the selectively heating process of a metal layer will be detailed in the following paragraph. To simplify the explanation and clarify the comparison, in the following exemplary embodiments, the same components are denoted by the same numerals, and the differences are discussed while the similarities are not described again. Please refer to FIG. 7 through FIG. 9. FIG. 7 through FIG. 9 illustrate a method for processing a metal layer according to the second exemplary embodiment of the present invention. As shown in FIG. 7, the semiconductor substrate 10 including at least a conductive region 12 is provided. The first layer 14 having a stepped surface is formed on the semiconductor substrate 10. The stepped surface of the first layer 14 includes a plurality of openings 28 which may expose the conductive regions 12 of the semiconductor substrate 10. In this exemplary embodiment, each of the openings 28 could be divided into the first opening 30 and the second opening 32.

Subsequently, the metal layer 20 is formed over the semiconductor substrate 10. The metal layer 20 is supposed to overall cover the first layer 14 and the semiconductor substrate 10, however, if any of the first openings 30 and the second openings 32 has a ratio of a height H1/H2 of the first opening 30/the second opening 32 to a width W1/W2 of the first opening 30/the second opening 32 substantially greater than 4, i.e. H1/W1>4 or H2/W2>4, some structural defects such as void structures 22 may be formed in the opening 28 between the metal layer 20 and the semiconductor substrate 10.

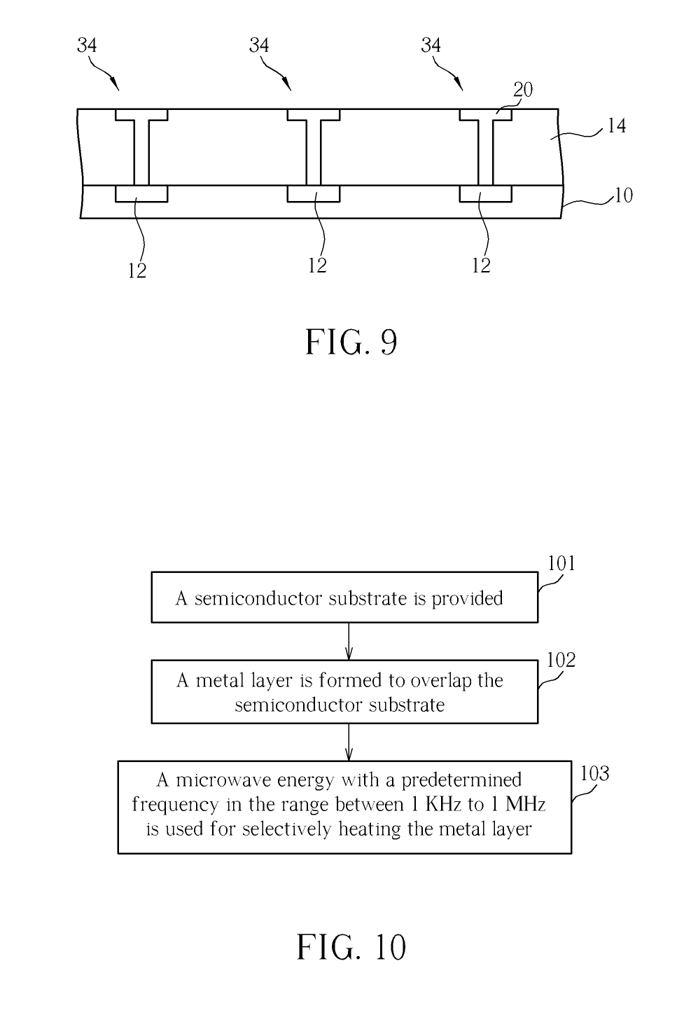

As shown in FIG. 9, as illustrated in the first exemplary embodiment, for compensating the phenomenon, a microwave energy 24 is used to selectively heat the metal layer 20. A temperature of the metal layer 20 may increase, and the metal layer 20 could reflow to fill up the void structure 22. Thus, the structural defects are reduced without redundant heat affecting the underlying semiconductor substrate 10 and other formed structures. It is appreciated that, the microwave energy 24 has a predetermined frequency depending on a material of the metal layer 20, and the feasible operating frequency ranges between 1 KHz to 1 MHz. For example, as the metal layer 20 is made of aluminum (Al), the preferred operating condition of the microwave energy 24 may include an operating frequency as 600 KHz and an operating period as 60 seconds.

Afterward, a planarization process such as a chemical mechanical polish (CMP) process is performed to remove the excess portion of the metal layer 20 above the first layer 14 to complete the formation of the metal interconnect structure 34 as a dual damascene structure. With the implementation of the microwave energy 24, the void free metal interconnect structure 34 is obtained.

Please refer to FIG. 10. FIG. 10 is a flow chart illustrating a method for processing a metal layer according to an exemplary embodiment of the present invention. As shown in step 101, at first, a semiconductor substrate such as a silicon substrate or a silicon-on-insulator (SOI) substrate is provided. The semiconductor substrate could be a blanket substrate or a structural wafer. For example, the semiconductor substrate may include an insulating layer having a stepped surface disposed thereon, and the stepped surface includes a plurality of openings with the same aspect ratios or different aspect ratios. The aspect ratio is a ratio of a height of the opening to a width of the opening. As shown in step 102, a metal layer is formed over the semiconductor substrate. For the constraint of the metal layer formation process such as CVD process or PVD process, as the semiconductor substrate includes openings or trenches having the aspect ratio greater than 4, the structural defect such as void structure may be formed in the opening between the semiconductor substrate and the metal layer. As shown in step 103, a microwave energy is used for selectively heating the metal layer, and the microwave energy has a predetermined frequency in accordance with a material of the metal layer, and the predetermined frequency ranges between 1 KHz to 1 MHz. Consequently, the structural defects between the semiconductor substrate and the metal layer may be eliminated.

In conclusion, the present invention utilizes microwave energy for processing a metal layer on the semiconductor substrate, the microwave energy has a predetermined frequency depending on a material of the metal layer, and the predetermined frequency ranges between 1 KHz to 1 MHz. Because the induced current provided by the microwave energy is centered on the surface of the metal layer as a heating source, the microwave energy may selectively heat the metal layer without affecting the underlying semiconductor substrate and other formed structures. This method may also be integrated into the metal interconnect process of small dimensional structure of 20 nm and beyond to overcome the constraint of the metal layer formation process such as CVD process or PVD process, consequently, the void free metal interconnect structure could be obtained for facilitating the reliability of semiconductor device performance.

Those skilled in the art will readily observe that numerous modifications and alterations of the device and method may be made while retaining the teachings of the invention.

What is claimed is:

1. A method for processing a metal layer, comprising:
providing a semiconductor substrate;
forming a metal layer over the semiconductor substrate; and
selectively heating the metal layer with a microwave energy, wherein the microwave energy has a predetermined frequency in accordance with a material of the metal layer, and the predetermined frequency ranges between 1 KHz to 1 MHz.

2. The method for processing a metal layer according to claim 1, further comprising:
forming a first layer having a stepped surface between the metal layer and the semiconductor substrate; and
forming at least a void structure between the metal layer and the semiconductor substrate.

3. The method for processing a metal layer according to claim 2, wherein the first layer comprises an insulating layer.

4. The method for processing a metal layer according to claim 3, wherein a material of the first layer comprises low-k (low dielectric constant) material.

5. The method for processing a metal layer according to claim 2, wherein the stepped surface of the first layer comprises a plurality of openings.

6. The method for processing a metal layer according to claim 5, wherein the opening exposes a conductive region.

7. The method for processing a metal layer according to claim 6, wherein the opening comprises a contact hole, a via hole, a plug hole, a trench or a dual damascene.

8. The method for processing a metal layer according to claim 5, wherein at least one of the openings comprises a ratio of a height of the opening to a width of the opening more than 4.

9. The method for processing a metal layer according to claim 5, wherein the void structure is formed in the opening.

10. The method for processing a metal layer according to claim 2, wherein a temperature of the metal layer increases, and the metal layer reflows to fill up the void structure by the selective heating step.

11. The method for processing a metal layer according to claim 1, wherein the material of the metal layer comprises aluminum (Al).

12. The method for processing a metal layer according to claim 11, wherein the microwave energy has an operating frequency as 600 KHz and an operating period as 60 seconds.
